(19) United States
(12) Patent Application Publication
(10) Pub. No.: US 2016/0048015 A1
(43) Pub. Date: Feb. 18, 2016

(54) DISPLAYS HAVING REDUCED OPTICAL SENSITIVITY TO APERTURE ALIGNMENT AT STEPPER FIELD BOUNDARY

(71) Applicant: Pixtronix, Inc., San Diego, CA (US)

(72) Inventors: Xiang-Dong Mi, Northborough, MA (US); Jignesh Gandhi, Burlington, MA (US); Timothy Brosnihan, Natick, MA (US); John Fijol, Shrewsbury, MA (US); Cait Ni Chleirigh, Burlington, MA (US); Aleksander Franz, Winchester, MA (US); Jianru Shi, Haverhill, MA (US); Stephen Robert Lewis, Portland, ME (US)

(21) Appl. No.: 14/458,717

(22) Filed: Aug. 13, 2014

(51) Int. Cl. G02B 27/00; G03F 9/00; G09G 3/34

(52) U.S. Cl. CPC G02B 27/0025; G09G 3/346; G03F 9/7046; G09G 2360/10; G09G 2310/027; G09G 2310/0267; G09G 2300/0842

(57) ABSTRACT

Systems, methods and methods of manufacture for, among other things, a MEMS display that has a substrate with a first and a second array of apertures. The first and second arrays are, typically, formed on the substrate so that the arrays are adjacent and define a field boundary line that may extend between the two arrays and along a width of the substrate. In at least one array, the apertures that are proximate the field boundary line are placed at locations on the substrate to reduce differences in luminance between one portion of the display and another portion of the display.

### TECHNICAL FIELD

This disclosure relates to the field of displays, and particularly to displays that include a plurality of light modulating devices and other electromechanical systems and devices.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

MEMS display devices are known in the art. Many MEMS display devices include a plurality of MEMS devices arranged into an array that is formed on a substrate. The array of MEMS devices modulates light as light passes through the array of devices. The modulated light travels toward an array of apertures and passes through the apertures to form an image on the screen of the display.

MEMS displays work very well to produce clear and attractive images. However, the quality of the image depends upon the alignment between the MEMS devices and the apertures that pass light to the screen of the display. Misalignment between the MEMS device and these apertures can negatively impact image quality. However, precise alignment can be difficult to achieve during manufacture.

Accordingly, it would be beneficial to the art to have displays that are less susceptible to image problems caused by misalignment arising during manufacture.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display device having apertures for passing light, and having a first substrate body with a first array of apertures arranged in a plurality of rows, and with a second array of apertures arranged in a plurality of rows. The first array may be arranged adjacent to the second array to define a boundary therebetween. A spatial separation between adjacent apertures proximate the boundary and in a first row varies from a spatial separation between adjacent apertures proximate the boundary and in a second row, to provide spatial dithering to light passing through the apertures.

In some implementations, the device can include apertures that have a length and a width, and a ratio of the length to the width is greater than four. In some implementations, the device can include a first array and a second array that are arranged in an interleaving pattern, to have portions of a row in the first array overlap with portions of a row in the second array. In some implementations, the first array and the second array have overlapping rows wherein an amount of overlap between the first and the second arrays increases over two or more rows. In some implementations, at least one aperture that is proximate the boundary has a peripheral edge including irregularly spaced deviations, which alters the spacing of the aperture from the boundary.

In some implementations, the variation in spatial separation between apertures reduces as a function of the distance from the boundary. In some implementations, a distance between an aperture and the boundary varies from aperture to aperture, and in some implementations, the variation may be according to a substantially random function or may be variations between a plurality of predefined distances.

In some implementations, the device can include a second substrate body having an array of apertures arranged in a plurality of rows and being arranged in an opposing position to the first substrate body to align an aperture in the first substrate body with an aperture in the second substrate body. In some implementations, the first substrate body and the second substrate body may be separated by a gap, and each respective aperture has a length and a width and a ratio of the gap to the width of the aperture is greater than 0.8.

In some implementations, the array of apertures on the second substrate body includes a third array of apertures arranged adjacent to a fourth array of apertures and having a second boundary therebetween, and a spatial separation between adjacent apertures proximate the second boundary varies along the length of the second boundary.

In some implementations, the device can include a plurality of display elements arranged to modulate light passing through the apertures, a processor capable of communicating with the display, the processor being capable of processing image data; and a memory device capable of communicating with the processor. In some implementations, the device can include a driver circuit capable of sending at least one signal to the display; and a controller capable of sending at least a portion of the image data to the driver circuit. In some implementations, the device can include an image source module capable of sending the image data to the processor, wherein the image source module includes at least one of a receiver, transceiver, and transmitter. In some implementations, the device can include an input device capable of receiving input data and communicating the input data to the processor.

Another innovative aspect of the subject matter described in this disclosure can be implemented in a method for reducing artifacts in an image, including providing a first substrate body having a first array of apertures arranged in a plurality of rows, and a second array of apertures arranged in a plurality of rows, arranging the first array adjacent to the second array to align rows in the first array with rows in the second array and to define a boundary between the first and second arrays, and spatially separating adjacent apertures proximate the boundary a distance that varies from row to row within at least one of the first and second arrays, to provide spatial dithering to light passing through the apertures.

Another innovative aspect of the subject matter described in this disclosure can be implemented in a method of manufacturing a display that passes a first portion of a substrate under a stepper to form a first array of apertures arranged in a plurality of rows, re-orients the substrate to pass a second portion of the substrate body under the stepper and forms a second array of apertures arranged in a plurality of rows and being arranged to align rows in the first array with rows in the second array and to define a boundary between the first and second arrays. The method forms apertures in the first array, in the second array, or in both the first and the second arrays to spatially separate adjacent apertures proximate the boundary a distance that varies from one row to another row within the array, to dither light passing through the apertures.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 2C is a perspective view of a shutter-based light modulator.

FIG. 3A shows a substrate having two arrays of apertures.

FIG. 3B shows a stepper patterning a substrate.

FIG. 4A is a cross-section view of a display formed from the light modulators depicted in FIG. 2C.

FIG. 4B depicts an aperture plate and a backplane used in a display having the light modulators of FIG. 4A.

FIG. 5 depicts a vertical line artifact at the field boundary line.

FIGS. 6A and 6B depict substrates having apertures arranged to reduce visual artifacts within a display.

FIG. 7 depicts a substrate that includes a staggered field boundary line.

FIG. 8 depicts a pair of apertures having an irregularly shaped peripheral edge.

FIG. 9 is a flowchart of a process for using a substrate to reduce visual artifacts.

FIG. 10 is a flowchart of a process for manufacturing a substrate to reduce visual artifacts.

FIGS. 11A and 11B are system block diagrams illustrating a display device that includes a plurality of shutter display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system including those that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including micro electromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Moreover, the teachings herein may be used in many applications that include MEMS devices that have components that come into contact during operation. Thus, the teachings are not intended to be limited to the implementations depicted solely in the Figures, but instead have wide applicability as will be readily apparent to one having ordinary skill in the art.

In certain implementations described herein, a MEMS display has a substrate with a first and a second array of apertures. The first and second arrays are, typically, formed on the substrate so that the arrays are adjacent and define a field boundary line that may extend between the two arrays and along a width of the substrate. In at least one array, the apertures that are proximate the field boundary line are placed at locations on the substrate to reduce differences in luminance between one portion of the display and another portion of the display. In one implementation, the apertures are placed at locations selected according to a spatial dithering process that arranges apertures to generate a selected luminance value for a portion of the display that is proximate the field boundary line.

In certain implementations, the MEMS display includes an aperture plate and a backplane. Both the aperture plate and the backplane are formed from a semiconductor substrate, such as an amorphous silicon (aSi) substrate, that has two arrays of apertures arranged side-by-side on the substrate. In the display, the aperture plate faces the backplane, and the apertures of the backplane are aligned with the apertures of the aperture plate. Light travels through the apertures of both the aperture plate and the backplane to form images on the display. At least some of the apertures on either of the backplane or the aperture plate are positioned according to a dithering process that places the aperture into a selected alignment with a corresponding aperture on the opposite substrate. The selected alignment between one aperture and its opposing aperture alters the luminance of the portion of the display associated with those aligned apertures.

In certain implementations, visual artifacts within a display, such as a vertical line artifact associated with a field boundary line, may be mitigated by spatial dithering of aperture spacing of those apertures that are proximate the field boundary line.

Particular implementations of the subject matter described in this disclosure can be implemented to realize one or more of the following potential advantages. The systems and methods described herein may reduce the deleterious effects of visual artifacts in a MEMS display by providing a process that adjusts the position of apertures to control the luminance of a portion of the display associated with that aperture. Certain implementations of the subject matter described in this disclosure can be implemented to realize one or more of the following other potential advantages, including providing a substrate that reduces visual artifacts on the display or controls the spatial luminance across the display.

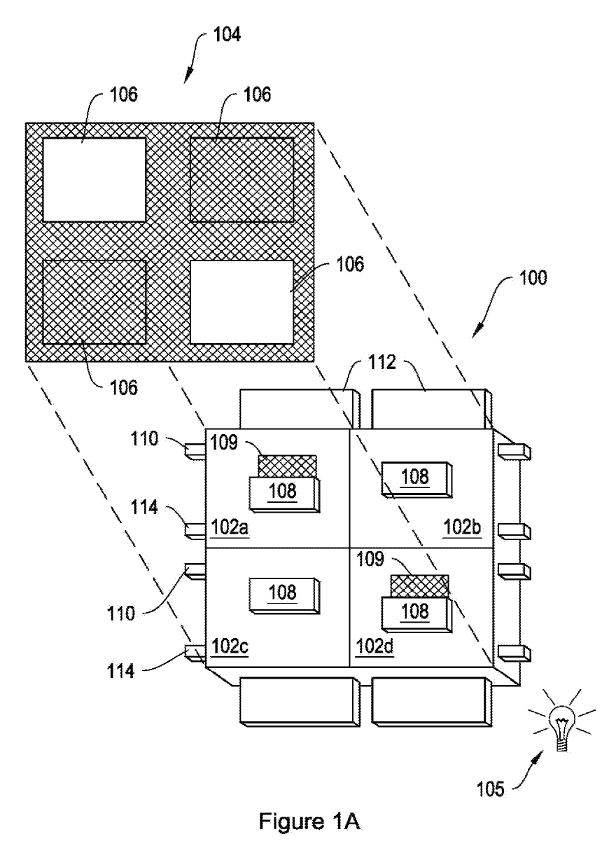

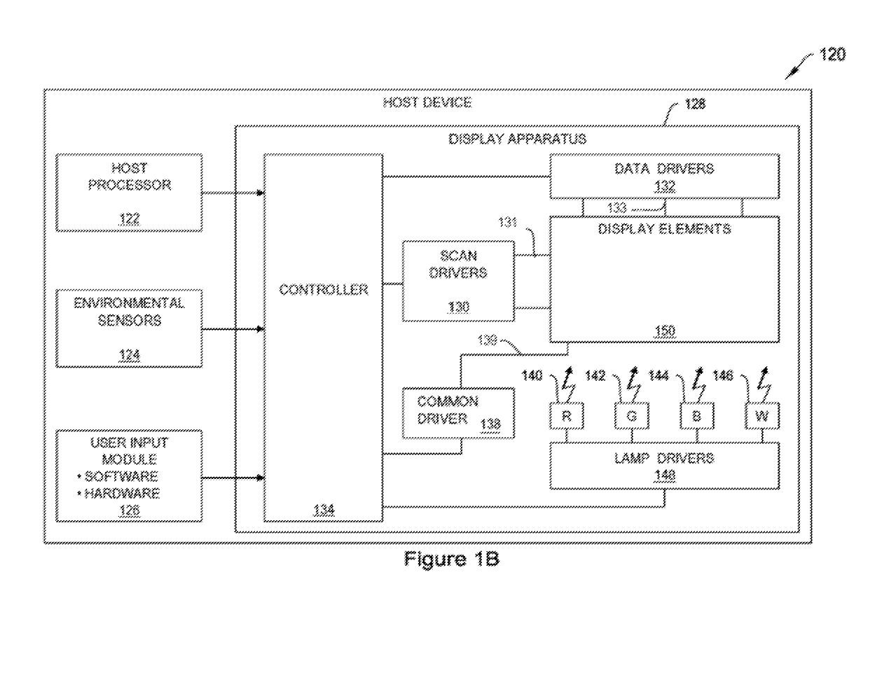

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, VWE), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying only a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for only a certain fraction of the image is loaded to the array of display elements 150. For example, the sequence can be implemented to address only every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

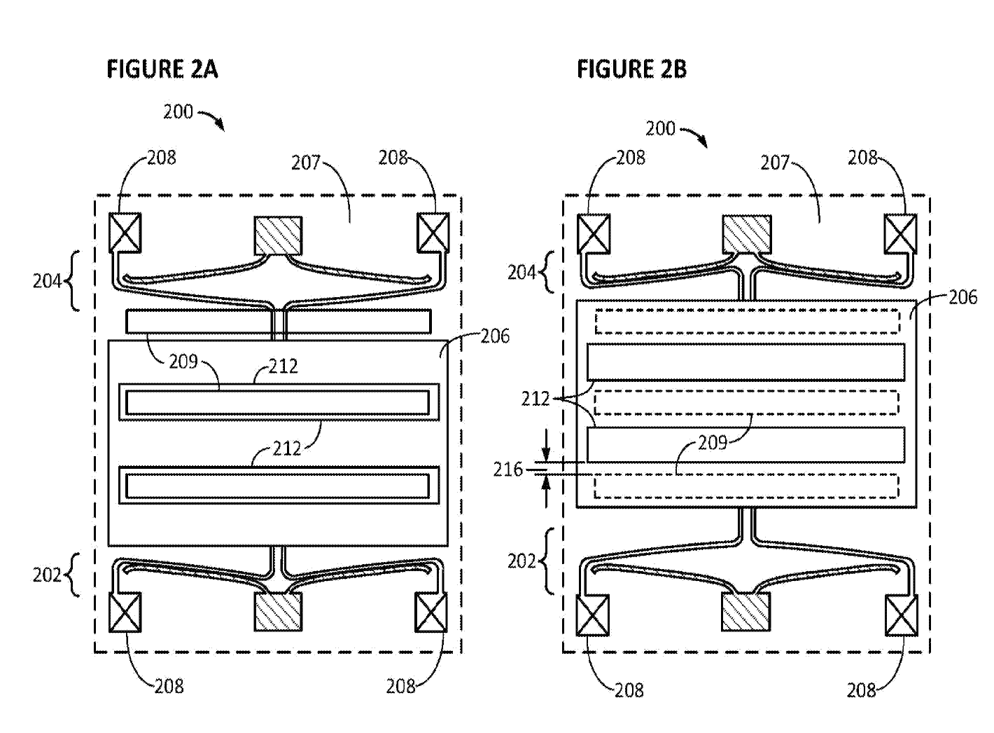

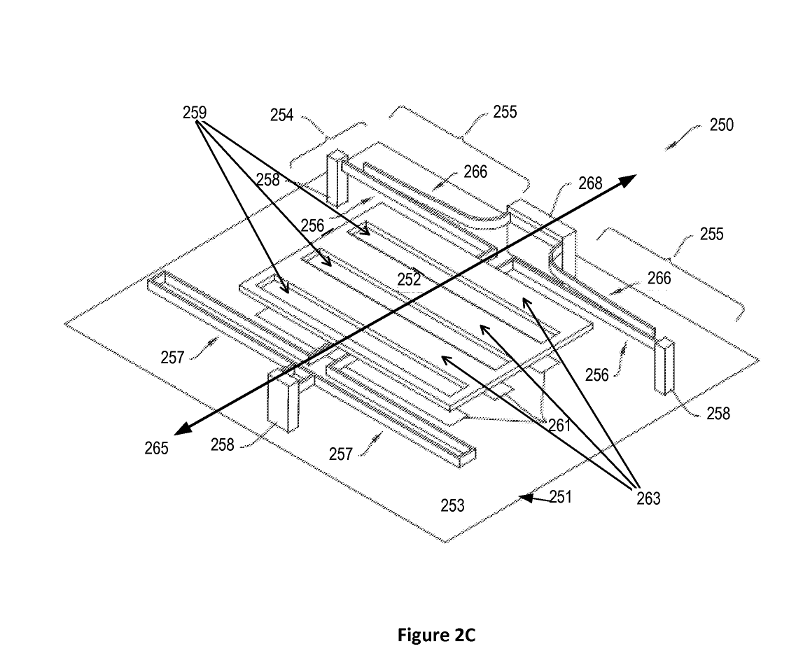

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture plate 207 over which the shutter is suspended. The shutter 206 is suspended a short distance over the aperture plate 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture plate 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture plate apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture plate 207, each aperture may have only a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture plate 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture plate 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vm.

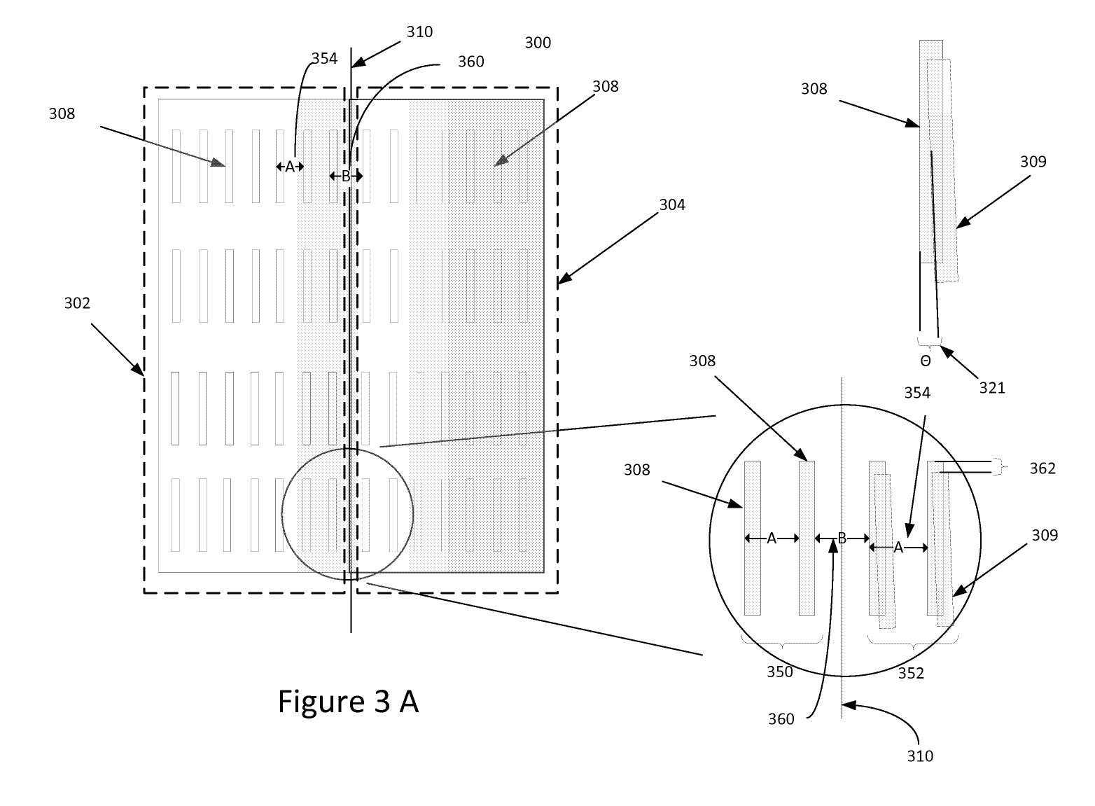

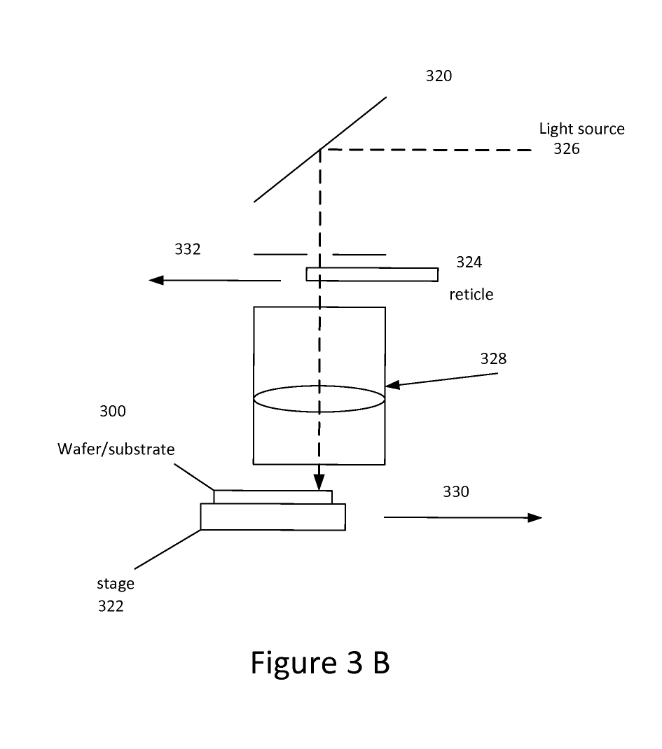

FIG. 3A shows a substrate having two arrays of apertures. In particular, FIG. 3A depicts a substrate 300 that includes a first array of apertures 302 and a second array of apertures of 304. The individual apertures 308 in the arrays are depicted as rectangular apertures arranged into rows and columns. The first array 302 is placed side-by-side with the second array 304 to define a field boundary line 310 that extends the width of the substrate 300 and that is positioned between the two arrays 302 and 304. In one implementation the substrate 300 is a semiconductor substrate such as a substrate formed of amorphous silicon (aSi). In one particular implementation, the substrate 300 has a width of about 110 mm, a length of about 165 mm, and a thickness of about 0.25-0.7 mm for a single display. Multiple displays, optionally, can be made on a glass substrate having a width of about 404 mm and a length of about 515 mm. The apertures 308 in this implementation are rectangular apertures that are 90 μm in length and 10 μm in width. The aperture length to width ratio is in this example 10, however it is generally greater than 4. The aperture length to width ratio is greater than that in a typical LCD, which is about 3 for a single color aperture. The apertures 308 may be through holes formed within the substrate 300, or may be optically transmissive regions formed in the substrate 308, or may be some other structure suitable for allowing light to pass through the substrate body. Other implementations may have apertures of different shapes and sizes.

Typically, the apertures 308 are formed within the substrate 300 by use of a stepper processing machine that positions the substrate 300 on a stage and moves the stage and substrate 300 beneath a light source that is patterned by passing the light source through a reticle. One example of such a stepper processing machine is the NanoTech 100 stepper that is manufactured and sold by UltraTech Inc. of San Jose, Calif. The stepper uses a light source that can affect properties of certain materials laid on the surface of the substrate 300 and chemical processes known in the art, create a pattern of apertures formed within the substrate 300, resulting in an array of apertures 308 formed in an array such as the array 302 or the array 304 depicted in FIG. 3A.

In certain implementations, the substrate 300 is large enough to require that the stepper operation take place in two or more steps. For the purpose of simplifying the discussion, the number of steps in the following examples is two. A first step forms one array of apertures, such as the array 302 depicted in FIG. 3A and a second step forms the second array of apertures 308, such as the array 304 depicted in FIG. 3A. The stepper forms the two arrays 302 and 304 so that they are arranged adjacent each other on the substrate 300 and separated by a field boundary line 310. One process for forming the two arrays 302 and 304 of apertures is depicted in FIG. 3B.

FIG. 3B shows a stepper patterning a substrate. In particular, FIG. 3B depicts a stepper 320 that has the substrate 300 on a stage 322. Light from a light source 326 is focused by optics 328 onto the substrate 300. A reticle 324, which is essentially a patterned mask, moves in a direction 332 opposite to the direction 330, which is the direction of movement of the substrate 300 on stage 322. For the large substrate 300, the stepper 320 moves a first portion of the substrate 300 underneath the light source 326. The first portion of the substrate 300 moved under light source 326 may correspond to the portion of the substrate 300 that is patterned with the array 302. Once the array 302 is patterned on to the substrate by the stepper 320, the substrate 300 may be removed from the stage 322 and re-oriented on the stage 322 so that the unpatterned portion of the substrate 300 may be moved by the stage 322 under the light source 326. This results in the formation of the array 304 depicted in FIG. 3A. The field boundary line 310 represents the boundary line between the two arrays 302 and 304, each formed by a separate pass of the substrate 300 beneath the stepper 320.

During manufacture the alignment between the first array 302 and the second array 304 may be imperfect and there may be some offset. Returning to FIG. 3A, an illustrative example of a first array that is offset from and misaligned with a second array is depicted. To this end, FIG. 3A includes an enlarged view of a section of the substrate 100 that includes two pairs of apertures 308, one pair on either side of the field boundary line 310. One pair 350 of apertures 308 is on the left of the field boundary line 310 and is part of the array 302. The second pair 352 is to the right of the field boundary line 300 and part of the array 304. Both pairs 350 and 352 include two apertures 308 that are separated from each other a distance 354, designated as “A” in the FIG. 3A. The distance “A” represents the pitch between two apertures 308. Specificially, the distance A is the distance between the beginning (or the end) of one aperture 308 and the beginning (or the end) of the adjacent aperture 308. During the manufacturing process, the pitch distance A is controlled to provide a consistent spacing between apertures 308, subject to a manufacturing tolerance. The manufacturing tolerance represents the variation in spacing that arises due to inaccuracies in the processes. The distance A represents the distance the manufacturing process spaces the apertures 308 apart, plus or minus the manufacturing tolerance.

FIG. 3A further illustrates that the aperture pairs 350 and 352 are separated across the field boundary line 300 and spaced apart a distance 360 designated as the pitch B. The pitch B is the distance between adjacent apertures 308 of the side-by-side arrays 302 and 304. Thus, the distance B is the spacing between the array 302 and the array 304. In one implementation, the pitch B represents the spacing achieved after the forming a first array and then repositioning the substrate 300 on the stage 322 to allow a second array to be formed on the substrate 300. Although typically, the pitch B is selected to be equal to the distance A, in actuality, A and B can differ because of the misalignment between the first array and the second array in the direction perpendicular to the field boundary line 310.

The difference in alignment between the two arrays 302 and 304 may also include a lateral offset, such as the lateral offset 362 depicted in FIG. 3A as well as a rotational offset, such as the rotational offset 321 depicted in FIG. 3A and represented by the angle displacement designated as 0 in FIG. 3A.

FIG. 3A illustrates a substrate 300 that has two arrays 302 and 304, each of which is formed by a separate processing step under a stepper, such as the stepper 320 in FIG. 3B. In other implementations, the substrate 300 may have more than two arrays, each formed during a separate processing step during which the substrate is repositioned on a stage 322 and an array of apertures is formed on the substrate. In additional variations, the substrate 300 may be any material suitable for supporting a plurality of optically transmissive apertures and may include glass, epitaxial silicon, plastic or any other suitable material. Additionally, the processes employed for forming the array may include a stepper, an ion beam, an electron beam, or any equipment suitable for forming, or being part of a process for forming, a plurality of optically transmissive arrays on a substrate.

The substrate 300 may be used as part of a MEMS display that employs a plurality of shutter-based light modulators. FIG. 2C is a perspective view of shutter-based light modulator. In certain implementations, a group of apertures 308, such as three apertures, on the substrate 300 is associated with a light modulator, such as the light modulator 250 shown in FIG. 2C. In certain implementations, the light modulator 250 is built onto the substrate 300, and therefore the substrate 300 would have an array of shutter-based light modulators. Each shutter-based light modulator 250 (also referred to as shutter assembly 250) includes a shutter 252 coupled to an actuator 254. The shutter 252 includes three slots 259 and three light blocking sections 263. The actuator 254 is formed from two separate compliant electrode beam actuators 255 (the “actuators 255”). The shutter 252 couples on one side to the actuators 255. The actuators 255 move the shutter 252 transversely over a surface 253 of the substrate 251 in a plane of motion which is substantially parallel to the surface 253. The opposite side of the shutter 252 couples to a spring 257 which provides a restoring force opposing the forces exerted by the actuator 254.

Each actuator 255 includes a compliant load beam 256 connecting the shutter 252 to a load anchor 258. The load anchors 258 along with the compliant load beams 256 serve as mechanical supports, keeping the shutter 252 suspended proximate to the surface 253 of substrate 251. The load anchors 258 physically connect the compliant load beams 256 and the shutter 252 to the surface 253 and electrically connect the load beams 256 to a bias voltage, in some instances, ground.

Each actuator 255 also includes a compliant drive beam 266 positioned adjacent to each load beam 256. The drive beams 266 couple at one end to a drive beam anchor 268 shared between the drive beams 266. The other end of each drive beam 266 is free to move. Each drive beam 266 is curved such that it is closest to the load beam 256 near the free end of the drive beam 266 and the anchored end of the load beam 256.

The substrate 251 includes one or more apertures 261 for admitting the passage of light. The apertures 261 are rectangular apertures similar to the apertures 308 depicted in FIG. 3A. If the shutter assembly 250 is formed on an opaque substrate 251, made for example from silicon, then the apertures 261 are formed by etching an array of holes through the substrate 251. If the shutter assembly 250 is formed on a transparent substrate 251, made for example of glass or plastic, then the surface 253 is a surface of a light blocking layer deposited on the substrate 251, and the apertures are formed by etching the surface 253 into an array of holes 261. The depicted apertures 261 are rectangular but optionally apertures 261 can be circular, elliptical, polygonal, serpentine, or irregular in shape. The depicted shutter 252 has three slots 263 that can be aligned with the apertures 261 of substrate 251. The alignment between the apertures 261 and the slots 263 controls, in part, the amount of light that can pass through the substrate 251 and pass through the shutter 252. The depicted slots 263 are rectangular, but any suitable shape or pattern may be employed.

In operation, a display apparatus incorporating the light modulator 250 applies an electric potential to the drive beams 266 via the drive beam anchor 268. A second electric potential may be applied to the load beams 256. The resulting potential difference between the drive beams 266 and the load beams 256 pulls the free ends of the drive beams 266 towards the anchored ends of the load beams 256, and pulls the shutter ends of the load beams 256 toward the anchored ends of the drive beams 266, thereby driving the shutter 252 transversely over the apertures 261 and towards the drive anchor 268. The compliant members 256 act as springs, such that when the voltage across the beams 256 and 266 is removed, the load beams 256 push the shutter 252 back into its initial position, allowing the shutter 252 to again pass over the apertures 261. The drive beams 266 and compliant members 256 move the shutter 252 transversely over the apertures 261, traveling back and forth along a linear path indicated by the line 265. In this way, light passing through the apertures 261 is modulated by the shutter moving the slots 263 in and out of alignment with the apertures 261.

The actuator 255 within the shutter assembly is said to operate between a first position and a second position, which for this depicted example is a closed or actuated position and a relaxed position. The shutter 252 moves between the open position, in which the slots 259 are aligned over the apertures 261 to allow light to travel from the apertures 261 and through the slots 259, and the closed position, in which the light blocking sections 263 are aligned over the apertures 261 to block light from traveling past the shutter 252.

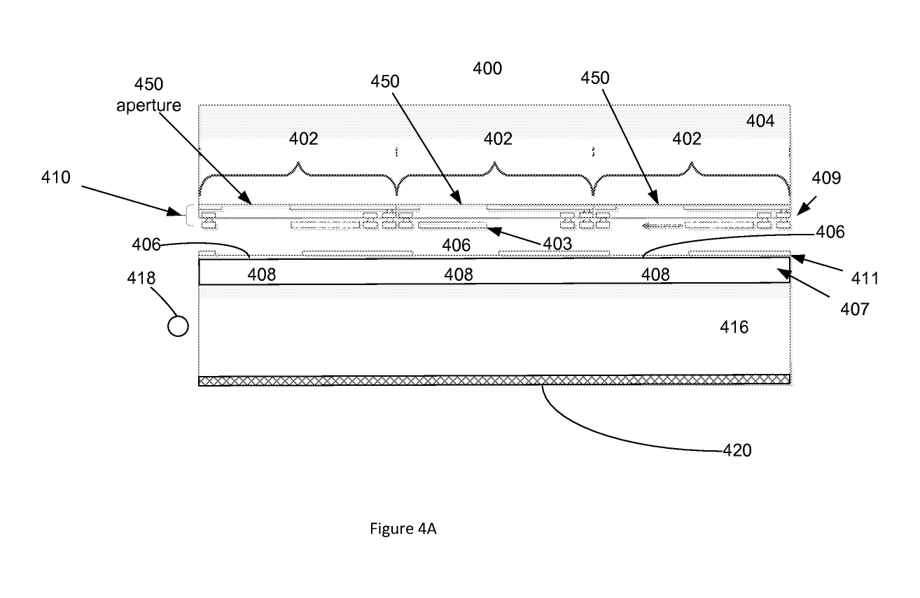

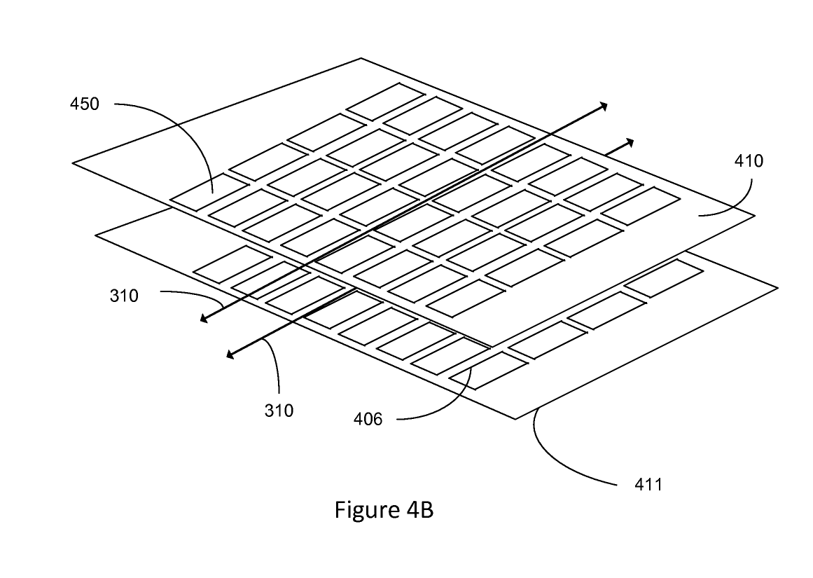

FIG. 4A is a cross-section view of a display formed of the light modulators depicted in FIG. 2C. In particular, FIG. 4A depicts a portion of a MEMS display 400 that includes three shutter assemblies 402 positioned between an aperture plate 408 and a transparent substrate 404. A light source 418 directs light into a light guide 416. The light guide 420 has a lower reflective surface 420 that directs light from the light source toward the aperture plate 408. The aperture plate 408 has a plurality of apertures 406, of which three are shown in FIG. 4A. The apertures 406 of FIG. 4A are designed to be each aligned with an opposing aperture 450 formed in the back plane 410. The back plane 410 may be a semiconductor substrate formed on the transparent substrate 404 and that supports the MEMS shutter assemblies 402, and to that end is similar to the substrate 251 depicted in FIG. 2C. In some cases, due to variations in manufacturing processes, the apertures 406 and opposing apertures 450 are misaligned by up to about 3 μm. The amount of misalignment between apertures 406 and opposing apertures 450 from one array such as the array 302 is typically different from the amount of misalignment between apertures 406 and opposing apertures 450 from the other array such as the array 304. This difference in misalignment causes a difference in light transmission, which in turn causes visual defect. Moreover, the difference in light transmission increases with gap between the apertures 406 and opposing apertures 450. A typical gap is between 8 μm and 13 μm. In one example, the gap to aperture width ratio is between 0.8 and 1.3. This gap to aperture ratio is greater than that in a typical LCD, which is less than 0.5.

Each shutter assembly 402 incorporates a shutter 403 and an anchor 405. Not shown are the compliant beam actuators which, when connected between the anchors 405 and the shutters 403, help to suspend the shutters a short distance away from the back plane 410. The shutter assemblies 402 on the back plane 410 are disposed on a transparent substrate 404 that may be made of plastic or glass or other suitable material. The gap which separates the shutters 403 from the back plane 410, within which the shutter is free to move, is in the range of about 0.5 to 10 μm.

The light guide 416 includes a transparent material, such as glass or plastic. The depicted light guide 416 is illuminated by one or more light sources 418, forming a backlight. The light sources 418 can be, for example, and without limitation, incandescent lamps, fluorescent lamps, lasers, or light emitting diodes (LEDs). A reflective film 420 is disposed behind the backlight 416, reflecting light towards the shutter assemblies 402.

FIG. 4A is a cross-sectional view of a MEMS-down implementation of a shutter-based display apparatus. In this MEMS-down configuration, the substrate 404 that carries the MEMS-based light modulators 402 may be the cover plate 422 in the display apparatus 400 and is oriented such that the MEMS-based light modulators 402 are positioned on the rear surface of the top substrate, i.e., the surface that faces away from the viewer and toward the back light 416. In the MEMS-down implementation, the MEMS-based light modulators 402 are positioned directly opposite to and across a gap from the aperture layer 300. The gap can be maintained by a number of spacer posts (not shown) connecting the aperture plate 407 and the substrate 404 on which the MEMS modulators 402 are formed. In some implementations, the spacer posts are disposed within or between each pixel in the array.

Accordingly, FIG. 4A depicts that the aperture layer 409 on top of the aperture plate 407 allows the light from the light source 418 to pass through the apertures 406. The apertures 406 are aligned with corresponding apertures 450 that are formed in the back plane 410 that is deposited on the glass substrate 404 that acts like the glass surface of the display.

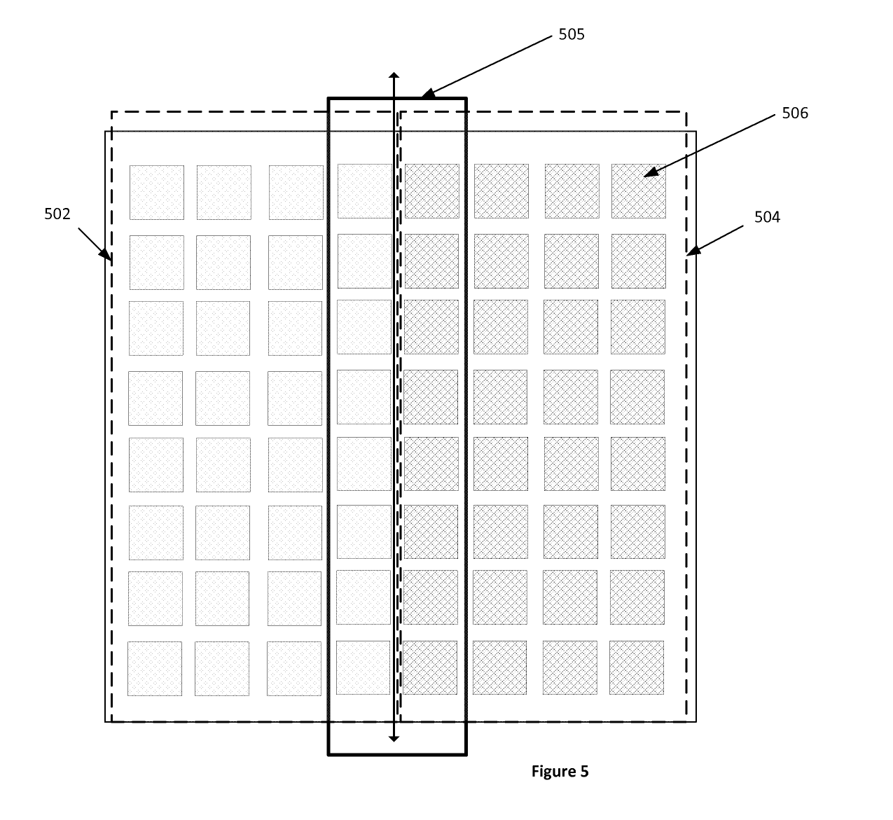

FIG. 4B depicts a perspective view of the aperture layer 411 and the back plane 410. For light to travel from the light guide 416 to the substrate 404, the apertures 406 must be aligned with the apertures 450. Misalignment between the apertures 406 and the apertures 450 will negatively impact the volume of light that passes from the light guide 416 through the substrate 404. This reduction in light volume will reduce the luminance of the display. FIG. 4B further shows that, in this implementation, the aperture layer 311 and the back plane 410 were both formed by processes that created the array of apertures in two steps. As shown in FIG. 4B, the back plane 410 includes an array of apertures 450 arranged in rows and columns. A field boundary line 310 extends through the center of the back plane 410 and divides the array of apertures into two separate arrays, a first one to the left of the field boundary line 310 and a second one to the right of field boundary line 310. Similarly, FIG. 4B shows that the aperture layer 311 includes a plurality of apertures 306 arranged in an array on the aperture layer 311. A field boundary line 310 extends through the center of the aperture layer 411 and divides the array of apertures 406 into a first array that is to the left of the field boundary line 310 and a second array that is to the right of the field boundary line 310. As described with reference to FIG. 3A the field boundary line 310 identifies the boundary of the stepper field employed to form the array of apertures. As such, the efficiency at which light passes from the light cavity 416 and through an opposing pair of apertures 406 and 450, turns at least in part on the alignment of those opposing apertures. Misalignment between an opposing pair of apertures 406 and 450 may reduce the luminance of a portion of the display, such as a pixel, associated with that pair of opposed apertures 406 and 450. As noted earlier, with regard to FIG. 3A, the spacing between adjacent apertures that are separated by the field boundary line 310 may differ from the spacing between adjacent apertures that are located away from the field boundary line 310. FIG. 5 depicts pictorially a group of adjacent apertures that are separated by a field boundary line 510.

FIG. 5 depicts a vertical line artifact at the field boundary line 510. In particular FIG. 5 depicts a substrate 500 that includes an array of apertures 506. A field boundary line 510 divides the array of apertures into a first array 502 and second array 504. Shading of array 504 is darker to indicate that the apertures 506 in array 504 have a lower luminance than the apertures 506 in the array 502. The difference in luminance creates a vertical artifact along field boundary line 510 because the adjacent apertures on either side of the field boundary 510 have different levels of luminance and this difference creates a stark visual effect, easily recognized as a boundary between a brighter part of the screen at array 502 and a darker part of the screen associated with array 504.

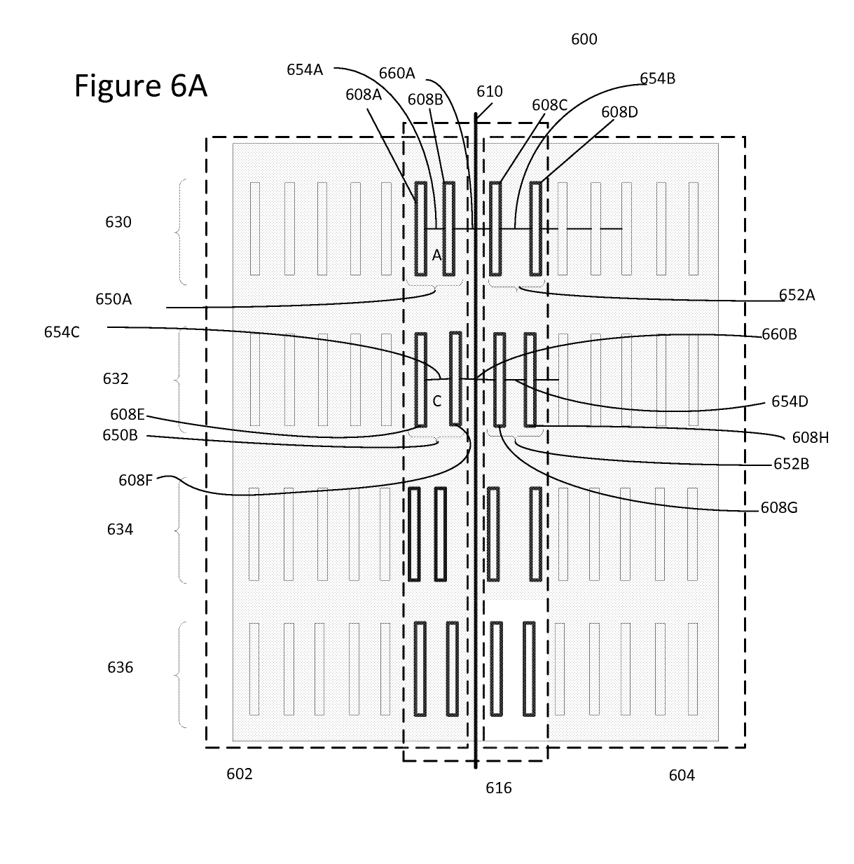

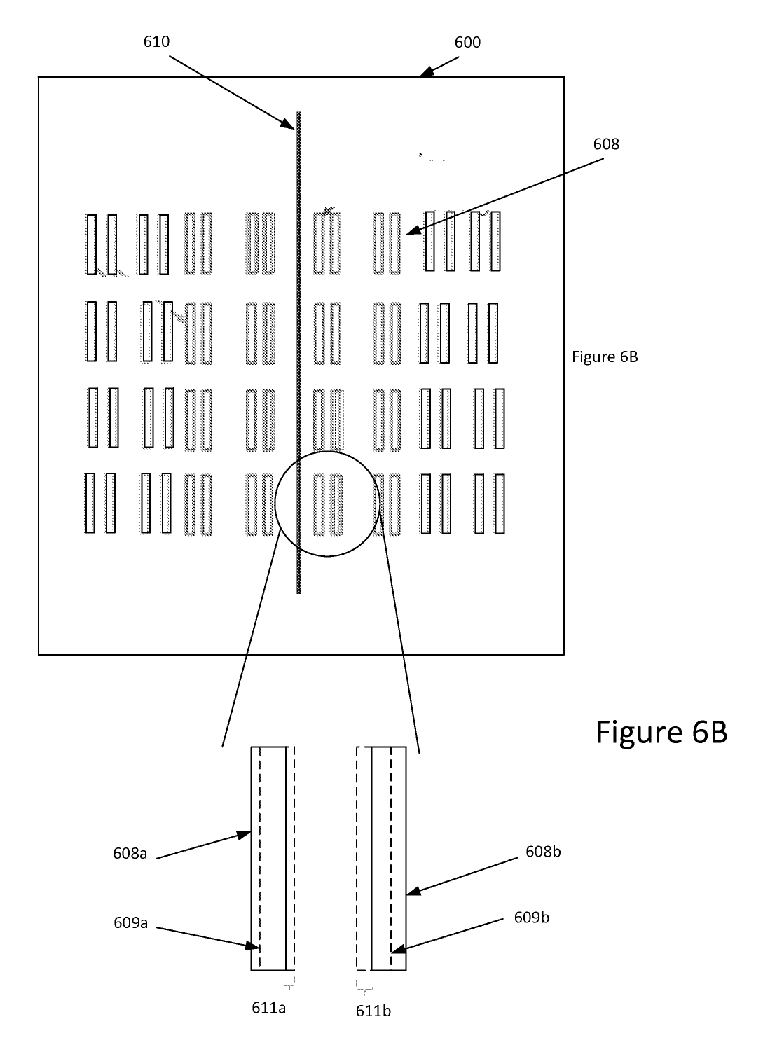

FIGS. 6A and 6B depict substrate having apertures arranged to reduce visual artifacts within a display. In particular, FIG. 6A depicts a substrate 600 that includes a plurality of apertures 608. The apertures 608 are arranged into a large array that includes two smaller arrays, a first smaller array 602 and a second smaller array 604. The arrays 602 and 604 are arranged adjacently on the substrate 600 and define a field boundary line 610 that extends between the arrays 602 and 604 for the length of the substrate 600. FIG. 6A depicts that the aperture pairs such as the depicted pair 650A and 652A that are on either side of the field boundary line 610, are arranged on the substrate 600 to provide spatial dithering and thereby provide an intermediate gray scale value about the field boundary line 610. The spatial dithering of the apertures 608 that are proximate to the field boundary line 610 provides a gray scale value that reduces the stark visual artifact that arises from differences in alignment between the apertures 608 and the corresponding apertures in the opposing array of apertures, such as the opposing array of apertures 406 shown in FIG. 4A.In the implementation depicted in FIG. 6A, the aperture pairs on either side of the field boundary line are spatially adjusted from row to row. For example, the pitch 654A between the apertures 608A and 608B in the aperture pair 650A is designated a distance A in row 630. In row 632, the spacing between aperture 608E and aperture 608F is a distance 654 designated as a distance C. The distances A and C are different and are selected to provide different luminance values for the portion of the display associated with the aperture pair 650A and the portion of the display associated with aperture pair 650B. Typically the portions of the display associated with each aperture 608 (including two small apertures 608A and 608B) are a pixel within the display. By altering the luminance of adjacent pixels across the field boundary line 610, the field boundary line becomes less visible

In FIG. 6A, aperture pairs on either side of field boundary line 610 are spatially dithered to provide intermediate values of gray scale across the field boundary line 610. To that end, the apertures 608C and 608D and aperture pair 652A are spaced apart a distance 654B. The distance 654B is different from the distance 654D which separates the apertures 608G and 608H in aperture pair 652B.

For the purpose of illustration, FIG. 6A exaggerates the change in location of the apertures 608 from their standard spacing, such as the spacing 354 depicted in FIG. 3A. However, typically the difference in spacing of an aperture 608 relocated in the array for the purpose of providing spatial dithering, is on the order of a fraction of the expected tolerance variation that arises during the manufacturing process that forms the aperture 608 within the substrate 600. By spatially dithering the location of an aperture 608 a distance that is a fraction of the expected tolerance variation, the aperture 608 is still largely aligned with an opposing aperture in an opposite aperture array, and thus most light passing through the aperture 608 will proceed onto and pass through the opposing aperture. However, by relocating the position of the aperture 608 so that it is spaced away a fraction of the expected tolerance variation, the luminance of the pixel formed by the opposing aperture pair has a modified luminance. If the relocation of the aperture 608 increases a misalignment between the aperture 608 and its opposing aperture in another plate, the relative luminance of that pixel will decrease. However, if the relocation of the aperture 608 by some fraction of the expected tolerance acts to improve the alignment of the aperture 608 with its opposing paired aperture in the opposite plate, the relative luminance of the associated pixel will increase. By varying from row to row, such as from rows 630-636, the location of the aperture 608, a varied and spatially distributed set of luminances will be achieved along the length of substrate 600 and on either side of the field boundary line 610. Then that result will be an intermediate value of luminance at the area of the field boundary line and a reduction in the visual impact of the change in luminance between the portion of the display associated with the array 604 and the luminance of the portion of the display associated with the array 602.

FIG. 6B illustrates using dashed lines the relative position of spatially dithered apertures 609 versus regularly spaced apertures 608 (which are shown with solid lines). In the exploded view in FIG. 6B of one pixel having two apertures, the left dithered aperture 609a is moved to the right side of regularly spaced aperture 608a, while the right dithered aperture 609b is moved to the left side of regularly spaced aperture 609b. The spatial offset is denoted by the brackets 611a and 611b, respectively. When light passes through the apertures in the aperture plate and dithered apertures in the back plane, the luminance angular profile is wider than when light passes through the same apertures on the aperture plate and regularly spaced apertures on the back plane. This wider averaged angular profile is less sensitive to misalignment difference between the pixel shown in the exploded view and the neighboring pixel that is on the other side of the field boundary line 610. In one implementation, the distance between the two paired apertures 608, 609 varies between about 5% and 20% of the width of the apertures. As illustrated, variation in spatial separation between apertures may reduce as a function of, such as in proportion to, the distance from the field boundary line and as apertures pairs increase in distance from the field boundary line 610, the spatial dithering may decrease, and the size of the offset may be between, for example, 1% and 5%. Thus, in some implementations, variation in spatial separation between apertures reduces as a function of the distance from the field boundary line. Moreover, FIG. 6B shows the spatial dithering of apertures 608 extending over a greater number of aperture pairs 650 than depicted in FIG. 6A. In particular, FIG. 6B depicts that aperture pairs that are spaced away from the field boundary line 610 can still have some spatial dithering. In certain implementations the amount of spatial dithering decreases with the distance of the aperture 608 from the field boundary line 610.

FIGS. 6A and 6B depict a single aperture plate being modified to spatially dither certain apertures within the array formed on the aperture plate. In certain implementations the apertures proximate the field boundary line in just one sub-array, such as the sub-array 602, are modified. In other implementations the apertures 608 proximate the field boundary line 610 in both sub-arrays 602 and 604 are spatially rearranged to provide dithering. Further, in certain implementations the apertures in both the aperture plate (such as plate 411) and apertures in the back plane (such as back plane 410 depicted in FIG. 4) are spatially modified to provide dithering in both the aperture plate 311 and the aperture array in the back plane 310.

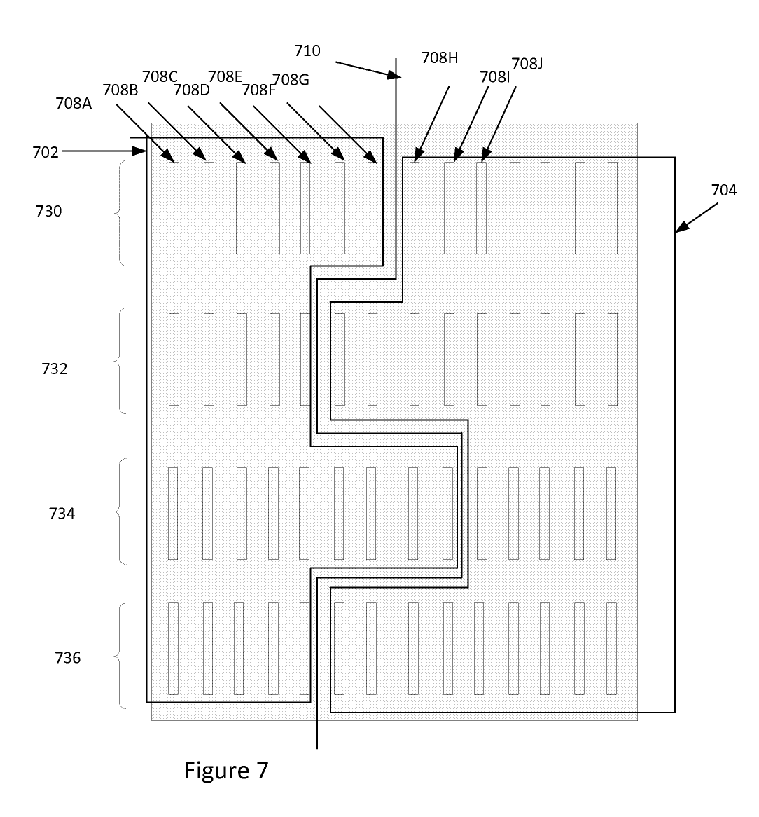

FIG. 7 depicts a substrate 700 that includes a staggered field boundary line 710. In particular FIG. 7 depicts a substrate 700 that has an array of apertures 708 formed on either side of a field boundary line 710. In the implementation of FIG. 7 the boundary line 710 is staggered so that the location of the field boundary line 710 varies from row to row. For example, the location of the field boundary line 710 in row 730 occurs between apertures 708G and 708H. In row 732 the field boundary line 710 is laterally offset from its position in row 730 and occurs between apertures 708E and 708F. The field boundary line 710 is laterally offset again in row 734 and returns to a location between apertures 7081 and 708J. The field boundary line 710 is laterally offset again, and this time passes between the apertures 708E and 708F in row 736. As depicted in FIG. 7, the field boundary line 710 has a staggered pattern that has a sub-array 702 interleave with the sub-array 704 so that the rows 730, 732, 734 and 736 overlap with each other. The staggered field boundary line 710 may be achieved in certain implementations, by controlling how the substrate 700 is moved within the stepper, such as the stepper 120 depicted in FIG. 1B. In particular, by controlling how the substrate 700 is moved under the reticle 124, the field boundary line 710 can be shaped in a staggered pattern to provide an array 702 that has apertures such as apertures 708H and 7081 that are formed as part of the array 702 during one stepper process operation, and the apertures 708F, 708G, 708H and 7081 in row 732 are part of array 704 which are formed during a different stepper operation. Thus, the tolerances of these overlapping apertures 708, vary from row to row thereby providing spatial dithering between contiguous rows 730 through 736 of the substrate 700. FIG. 7 depicts one example of a staggered field boundary line 710. In other implementations, the field boundary line 710 may have an increasing lateral offset from row to contiguous row so that the apertures formed during one stepper operation extend further into an array formed in a different stepper operation, providing a field boundary line with a staircase pattern over at least several rows of the aperture array.

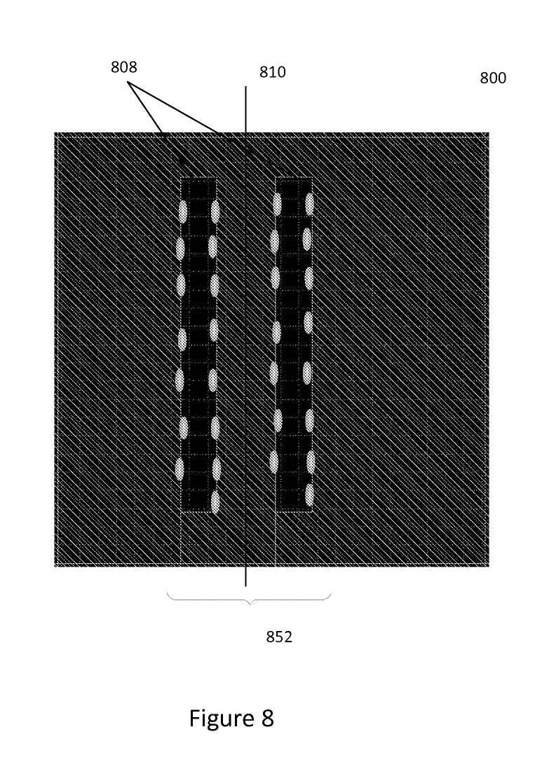

FIG. 8 depicts a pair of apertures having an irregularly shaped peripheral edge. In particular, FIG. 8 depicts a pair of apertures that have a peripheral edge that includes irregularly spaced non-linear deviations. The substrate 800 may have a full array of apertures 808 formed on it, but for ease of illustration, FIG. 8 depicts just the aperture pair 852 and that includes apertures 808A and 808B. Each aperture 808A and 808B has a peripheral edge that is irregularly formed so that the aperture's passing of light to its opposing aperture is varied. The irregular shape of the peripheral edge of the aperture 808A may be different from the irregular shape of the aperture 808B. In the implementation depicted in FIG. 8 the apertures 808A and 808B are on either side of the field boundary line 810. In certain implementations each aperture 808 within the array of apertures 808 formed on the substrate 800 may have an irregularly shaped peripheral edge. In certain implementations the variation between an aperture and the distance for the boundary varies according to a substantially random function. The random function can be any suitable random function, such as a psuedo-random number generator, capable of introducing a level of randomness into the process of shaping the apertures, such as shaping the irregular peripheral edge of the aperture or into the process of locating the apertures relative to the field boundary line. In some other implementations, the variation in distance between an aperture and the field boundary varies between a plurality of distances of predefined lengths. For example, there may be two predefined distances, one that is 10% more than the standard pitch and one that is 10% less, and the variation in distance between and aperture will be either of these two distances. In some implementations, the amount of irregularity built into the peripheral edge varies as a function of the distance of the respective aperture from the field boundary line 810. As apertures 808 are spaced farther from the field boundary line 810, the irregularity of the peripheral edge may decrease. The apertures 808 have a decreasing irregularity as they are spaced further from the field boundary line 810. The amount that the regularity decreases may be based, in some implementations, on a predefined pattern, such as reducing by half the amount of the irregularity built into a pattern each time an aperture is spaced one pitch from the field boundary line. In other implementations, the variation in irregularity between an aperture and the distance from the boundary varies according to a substantially random function, and the amount of variation will randomly change until a distance is reached at which apertures are given regular edges. In the cross-sectional view of the display shown in FIG. 4A, there are some dielectric layers. Dielectric layers such as SiO2 and SiNx are transparent, but can also reflect light because of their large indices of refraction. To increase light transmission through the aperture, the dielectric layers having high index of refraction are sometimes etched away and then filled with materials with lower index of refraction. In one implementation, a random edge profile is also added to the dielectric apertures to increase randomness of light angular distribution. This results in a less visible field boundary line.

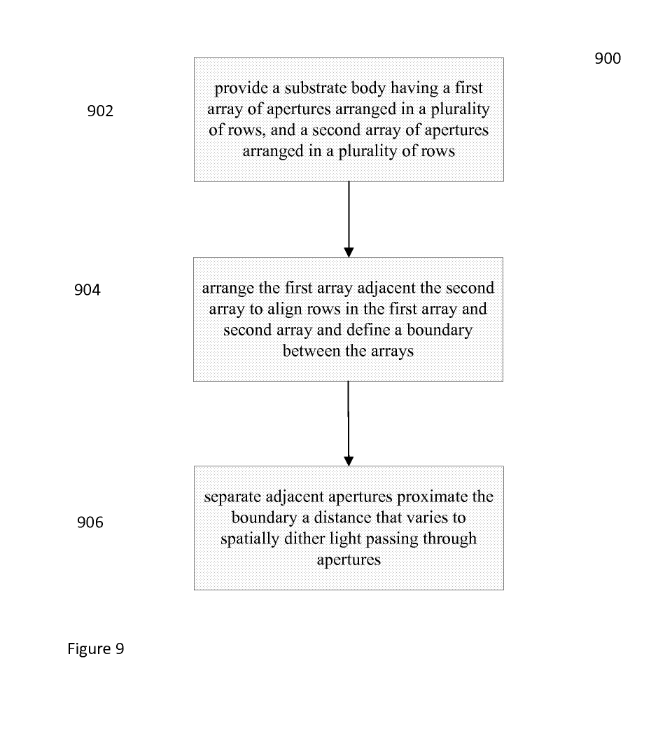

In another aspect, the systems and methods described herein include a method for reducing artifacts in an image. FIG. 9 is a flowchart of a process for using a substrate to reduce visual artifacts. FIG. 9 is a flowchart of a process 900 that includes a process operation 902 of providing a substrate body that has a first array of apertures arranged into rows and typically columns. The substrate body can also have a second array of apertures arranged into rows and typically columns. The process 900 proceeds to operation 904 and arranges the first array to be adjacent the second array and has the rows in the arrays aligned. A boundary is defined between the two arrays. The process 900 proceeds to operation 906. In operation 906 the process 900 separates adjacent apertures proximate the boundary a distance that varies from row to row within at least one of the first and second arrays. The process 900 can provide spatial dithering to light passing through the apertures along the boundary.

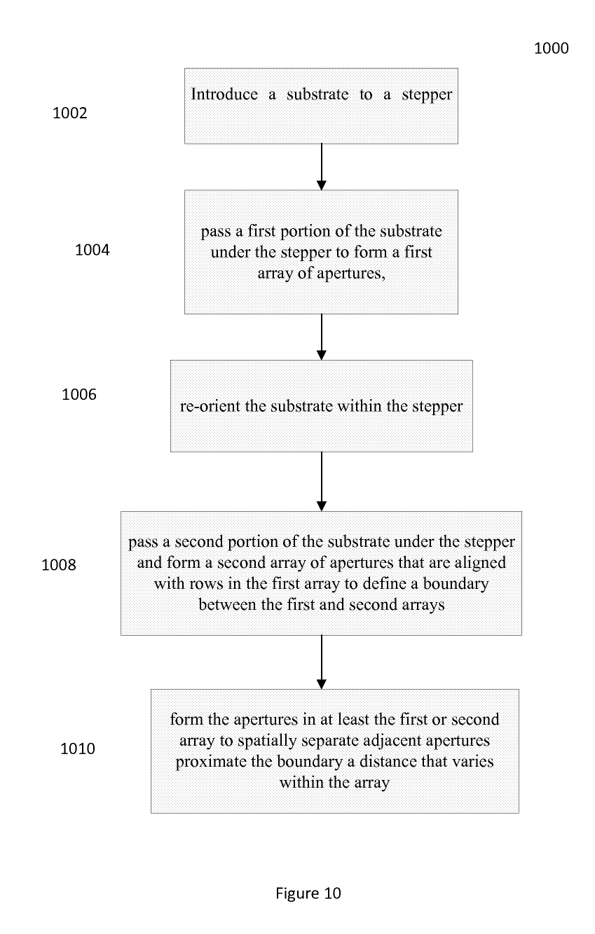

In another aspect, the systems and methods described herein include manufacturing processes that manufacture an array of apertures wherein the location of the apertures within the array is selected according to a spatial dithering process that reduces visual artifacts. FIG. 10 is a flowchart of a process for manufacturing a substrate to reduce visual artifacts. FIG. 10 shows a flowchart of a process 1000 that includes an operation 1002 that introduces a substrate into a processing station, such as a stepper or other suitable system. In 1004 a first portion of the substrate is passed under the stepper to form a first array of apertures. In 1006, the process 1000 re-orients the substrate within the stepper to pass a second portion of the substrate body under the stepper and form a second array of apertures. In 1008 the apertures of the second array are arranged in rows and typically columns. The apertures of the second array are arranged to align with rows in the first array and to define a boundary between the first and second arrays. In 1010, the process 1000 forms the apertures in at least the first or second array to spatially separate adjacent apertures proximate the boundary a distance that varies from one row to another row within the array, to dither light passing through apertures. In one implementation, the process is an iterative process that selects a dithering space, forms the two aperture layers and a display, and examines the visibility of the field boundary line and luminance of the pixels near filed boundary line. When the luminance drops under an unacceptable level, a threshold dithering level is found. In one implementation, the spatial dithering process is started by selecting a distance that is within half the width of the aperture, and offsetting the aperture by this selected distance. This selected distance can be the first dithering space tested by the iterative process. Returning to FIG. 3B, in one process the stepper 320 couples to a computer system that controls movement of the stage 322. The stage 322 moves the substrate 300 in a pattern that allows the light source to pass through the reticle and form apertures on the substrate 300. As described above with reference to FIG. 6A, the stage 322 may, under the control of the computer 360, alter the position of apertures 308 that are adjacent or otherwise proximate the field boundary line 310. For example, the computer program may control operation of the stage 322 so that the location of apertures such as aperture 608C depicted in FIG. 6A is spatially offset from the uniform spacing provided between other apertures 608 within the array.

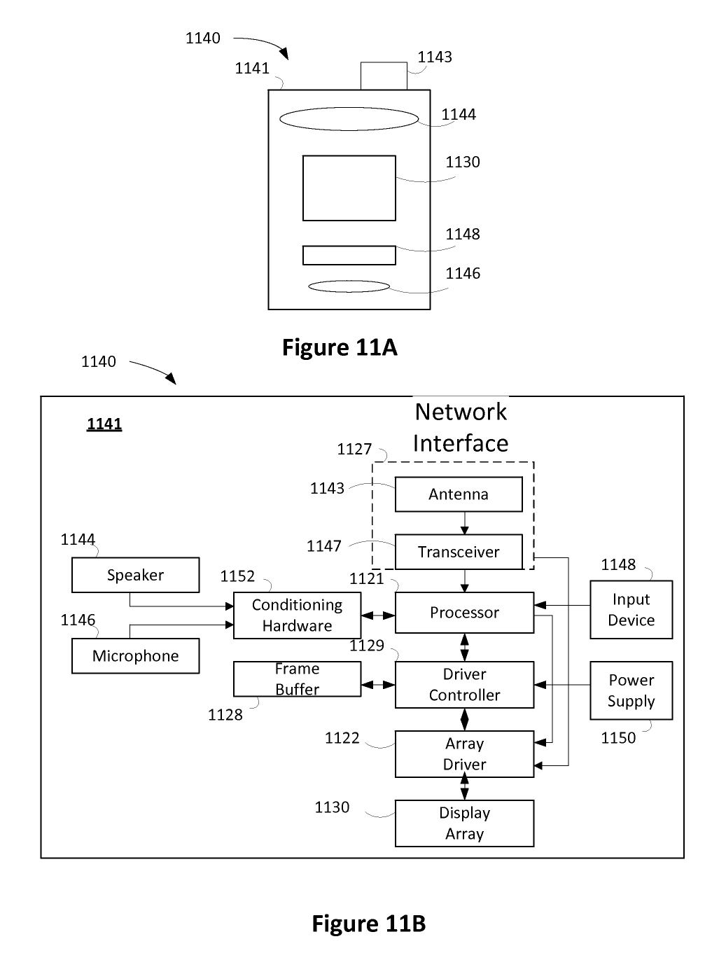

FIGS. 11A and 11B are system block diagrams illustrating a display device 1140 that includes a plurality of MEMS displays elements, including for example, DMS display elements. The display device 1140 can be, for example, a smart phone, a cellular or mobile telephone. However, the same components of the display device 1140 or slight variations thereof are also illustrative of various types of display devices such as televisions, computers, tablets, e-readers, hand-held devices and portable media devices.

The display device 1140 includes a housing 1141, a display 1130, an antenna 1143, a speaker 1145, an input device 1148 and a microphone 1146. The housing 1141 can be formed from any of a variety of manufacturing processes, including injection shuttering, and vacuum forming. In addition, the housing 1141 may be made from any of a variety of materials, including, but not limited to: plastic, metal, glass, rubber and ceramic, or a combination thereof. The housing 1141 can include removable portions (not shown) that may be interchanged with other removable portions of different color, or containing different logos, pictures, or symbols.

The display 1130 may be any of a variety of displays, including a bi-stable or analog display, as described herein. The display 1130 also can be configured to include a flat-panel display, such as plasma, EL, OLED, STN LCD, or TFT LCD, or a non-flat-panel display, such as a CRT or other tube device. In addition, the display 1130 can include, for example, a MEMS element based, as described herein.

The components of the display device 11 are schematically illustrated in FIG. 11B. The display device 1140 includes a housing 1141 and can include additional components at least partially enclosed therein. For example, the display device 1140 includes a network interface 1127 that includes an antenna 1143 which can be coupled to a transceiver 1147. The network interface 1127 may be a source for image data that could be displayed on the display device 1140. Accordingly, the network interface 1127 is one example of an image source module, but the processor 1121 and the input device 1148 also may serve as an image source module. The transceiver 1147 is connected to a processor 1121, which is connected to conditioning hardware 1152. The conditioning hardware 1152 may be configured to condition a signal (such as filter or otherwise manipulate a signal). The conditioning hardware 1152 can be connected to a speaker 1145 and a microphone 1146. The processor 1121 also can be connected to an input device 1148 and a driver controller 1129. The driver controller 1129 can be coupled to a frame buffer 1128, and to an array driver 1122, which in turn can be coupled to a display array 1130. One or more elements in the display device 1140, including elements not specifically depicted in FIG. 11B, can be configured to function as a memory device and be configured to communicate with the processor 1121. In some implementations, a power supply 1150 can provide power to substantially all components in the particular display device 1140 design.

The network interface 1127 includes the antenna 1143 and the transceiver 1147 so that the display device 1140 can communicate with one or more devices over a network. The network interface 1127 also may have some processing capabilities to relieve, for example, data processing requirements of the processor 1121. The antenna 1143 can transmit and receive signals. In some implementations, the antenna 1143 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 1143 transmits and receives RF signals according to the Bluetooth® standard. In the case of a cellular telephone, the antenna 1143 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 1147 can pre-process the signals received from the antenna 1143 so that they may be received by and further manipulated by the processor 1121. The transceiver 1147 also can process signals received from the processor 1121 so that they may be transmitted from the display device 1140 via the antenna 1143.

In some implementations, the transceiver 1147 can be replaced by a receiver. In addition, in some implementations, the network interface 1127 can be replaced by an image source, which can store or generate image data to be sent to the processor 1121. The processor 1121 can control the overall operation of the display device 1140. The processor 1121 receives data, such as compressed image data from the network interface 1127 or an image source, and processes the data into raw image data or into a format that can be readily processed into raw image data. The processor 1121 can send the processed data to the driver controller 1129 or to the frame buffer 1128 for storage. Raw data typically refers to the information that identifies the image characteristics at each location within an image. For example, such image characteristics can include color, saturation and gray-scale level.

The processor 1121 can include a microcontroller, CPU, or logic unit to control operation of the display device 1140. The conditioning hardware 1152 may include amplifiers and filters for transmitting signals to the speaker 1145, and for receiving signals from the microphone 1146. The conditioning hardware 1152 may be discrete components within the display device 1140, or may be incorporated within the processor 1121 or other components.

The driver controller 1129 can take the raw image data generated by the processor 1121 either directly from the processor 1121 or from the frame buffer 1128 and can re-format the raw image data appropriately for high speed transmission to the array driver 1122. In some implementations, the driver controller 1129 can re-format the raw image data into a data flow having a raster-like format, such that it has a time order suitable for scanning across the display array 1130. Then the driver controller 1129 sends the formatted information to the array driver 1122. Although a driver controller 1129, such as an LCD controller, is often associated with the system processor 1121 as a stand-alone Integrated Circuit (IC), such controllers may be implemented in many ways. For example, controllers may be embedded in the processor 1121 as hardware, embedded in the processor 1121 as software, or fully integrated in hardware with the array driver 1122.

The array driver 1122 can receive the formatted information from the driver controller 1129 and can re-format the video data into a parallel set of waveforms that are applied many times per second to the hundreds, and sometimes thousands (or more), of leads coming from the display's x-y matrix of display elements.

In some implementations, the driver controller 1129, the array driver 1122, and the display array 1130 are appropriate for any of the types of displays described herein. For example, the driver controller 1129 can be a conventional display controller or a bi-stable display controller (such as a MEMS element display controller, including for example, a DMS display controller). Additionally, the array driver 1122 can be a conventional driver or a bi-stable display driver (such as a MEMS element display driver, including for example, a DMS element display driver). Moreover, the display array 1130 can be a conventional display array or a bi-stable display array (such as a display including an array of MEMS elements, including for example, DMS display elements). In some implementations, the driver controller 1129 can be integrated with the array driver 1122. Such an implementation can be useful in highly integrated systems, for example, mobile phones, portable-electronic devices, watches or small-area displays.

In some implementations, the input device 1148 can be configured to allow, for example, a user to control the operation of the display device 1140. The input device 1148 can include a keypad, such as a QWERTY keyboard or a telephone keypad, a button, a switch, a rocker, a touch-sensitive screen, a touch-sensitive screen integrated with the display array 1130, or a pressure- or heat-sensitive membrane. The microphone 1146 can be configured as an input device for the display device 1140. In some implementations, voice commands through the microphone 1146 can be used for controlling operations of the display device 1140.

The power supply 1150 can include a variety of energy storage devices. For example, the power supply 1150 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 1150 also can be a renewable energy source, a capacitor, or a solar cell, including a plastic solar cell or solar-cell paint. The power supply 1150 also can be configured to receive power from a wall outlet.

In some implementations, control programmability resides in the driver controller 1129 which can be located in several places in the electronic display system. In some other implementations, control programmability resides in the array driver 1122. The above-described optimization may be implemented in any number of hardware and/or software components and in various configurations.

As used herein, a phrase referring to “at least one of a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., a MEMS display element, including for example, a DMS display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display device having apertures for passing light, comprising:
a first substrate body having a first array of apertures arranged in a plurality of rows, and a second array of apertures arranged in a plurality of rows,
the first array arranged adjacent the second array to define a boundary there between, wherein a spatial separation between adjacent apertures proximate the boundary and in a first row varies from a spatial separation between adjacent apertures proximate the boundary and in a second row, to provide spatial dithering to light passing through the apertures.

2. The display device of claim 1, wherein each of the first and second arrays of apertures has a length and a width, and a ratio of the length to the width is greater than four.

3. The display device according to claim 1, wherein the first array and the second array are arranged in an interleaving pattern, to have portions of a row in the first array overlap with portions of a row in the second array.

4. The display device according to claim 3, wherein an amount of overlap between the first and the second arrays increases over two or more rows.

5. The display device according to claim 1, wherein at least one aperture proximate the boundary has a peripheral edge including irregularly spaced deviations, which alters the spacing of the aperture from the boundary.

6. The display device according to claim 1, wherein a variation in spatial separation between apertures reduces as a function of the distance from the boundary.

7. The display device according to claim 1, wherein a distance between an aperture and the boundary varies from aperture to aperture.

8. The display device according to claim 7, wherein the variation between an aperture and the boundary varies according to a substantially random function.

9. The display device according to claim 7, wherein the variation in distance between an aperture and the boundary varies between a plurality of predefined distances.

10. The display device according to claim 1, further comprising
a second substrate body having an array of apertures arranged in a plurality of rows and being arranged in an opposing position to the first substrate body to align an aperture in the first substrate body with an aperture in the second substrate body.

11. The display device according to claim 10, wherein the first substrate body and the second substrate body are separated by a gap, and wherein each respective aperture has a length and a width, and a ratio of the gap to the width of the aperture is greater than 0.8.

12. The display device according to claim 10, wherein the array of apertures on the second substrate body includes
a third array of apertures arranged adjacent to a fourth array of apertures and having a second boundary there between, and a spatial separation between adjacent apertures proximate the second boundary varies along the length of the second boundary.

13. The display device of claim 1, further comprising
a plurality of display elements arranged to modulate light passing through the apertures,
a processor capable of communicating with the display, the processor being capable of processing image data; and
a memory device capable of communicating with the processor.

14. The display device of claim 13, further comprising:
a driver circuit capable of sending at least one signal to the display; and
a controller capable of sending at least a portion of the image data to the driver circuit.

15. The display device of claim 13, further comprising:
an image source module capable of sending the image data to the processor, wherein the image source module includes at least one of a receiver, transceiver, and transmitter.

16. The display device of claim 13, further comprising:
an input device capable of receiving input data and communicating the input data to the processor.

17. A method for reducing artifacts in an image, comprising:
providing a first substrate body having a first array of apertures arranged in a plurality of rows, and a second array of apertures arranged in a plurality of rows,
arranging the first array adjacent the second array to align rows in the first array with rows in the second array and to define a boundary between the first and second arrays, and
spatially separating adjacent apertures proximate the boundary a distance that varies from row to row within at least one of the first and second arrays, to provide spatial dithering to light passing through the apertures.

18. The method according to claim 17, further comprising
arranging the first array and the second array in an interleaving pattern, to have portions of a row in the first array overlap with portions of a row in the second array.

19. The method according to claim 17, further comprising arranging the first array and the second array to have overlapping rows, wherein an amount of overlap increases over two or more rows.

20. The method according to claim 17, further comprising providing at least one aperture proximate the boundary with a peripheral edge having irregularly spaced deviations.

21. The method according to claim 17, further comprising reducing the spatial variation between apertures as a function of the distance from the boundary.

22. The method according to claim 17, further comprising altering the variation between an aperture and the boundary according to a substantially random function.

23. The method according to claim 17, further comprising
providing a second substrate body having an array of apertures arranged in a plurality of rows, and
arranging the second substrate body in an opposing position to the first substrate body to align an aperture in the first substrate body with an aperture in the second substrate body.

24. The method according to claim 23, wherein the array of apertures on the second substrate body includes a third array of apertures arranged adjacent to a fourth array of apertures and having a second boundary there between, and a spatial separation between adjacent apertures proximate the second boundary varies along the length of the second boundary.

25. A method of manufacturing a display, comprising:
passing a first portion of a substrate under a stepper to form a first array of apertures arranged in a plurality of rows,
re-orienting the substrate to pass a second portion of the substrate under the stepper and forming a second array of apertures arranged in a plurality of rows and being arranged to align rows in the first array with rows in the second array and to define a boundary between the first and second arrays, and
forming apertures in the first array, in the second array, or in both the first and the second arrays to spatially separate adjacent apertures proximate the boundary a distance that varies from one row to another row within the array, to dither light passing through the apertures.

26. The method according to claim 25, further comprising:
forming the first and second arrays to overlap portions of a row in the first array with portions of a row in the second array.

27. The method according to claim 26, further comprising arranging the first array and the second array to have overlapping rows wherein an amount of overlap increases over two or more rows.

28. The method according to claim 25, including reducing the spatial variation between apertures as a function of the distance from the boundary.

29. The method according to claim 25, wherein forming apertures in at least one of the first or second arrays, includes forming apertures in both the first and second arrays to spatially separate adjacent apertures proximate the boundary a distance that varies from one row to another row within the array.

30. The method according to claim 25, further comprising:
arranging the first substrate in an opposing position to a second substrate having a third array of apertures to align an aperture in the first substrate with an aperture in the second substrate.
